(19) United States
(12) Patent Application Publication
(10) Pub. No.: US 2025/0157979 A1
(43) Pub. Date: May 15, 2025

(54) REFLOW FLIP CHIP BONDING TOOL APPARATUS AND OPERATING METHOD THEREOF

(71) Applicant: Electronics and Telecommunications Research Institute, Daejeon (KR)

(72) Inventors: Sang Jin KWON, Daejeon (KR); Jong Jin LEE, Daejeon (KR)

(73) Assignee: Electronics and Telecommunications Research Institute, Daejeon (KR)

(21) Appl. No.: 18/939,887

(22) Filed: Nov. 7, 2024

(30) Foreign Application Priority Data
Nov. 9, 2023 (KR) 10-2023-0154279
Jun. 19, 2024 (KR) 10-2024-0079455

(51) Int. Cl. H01L 23/00; B23K 1/00; B23K 1/002; B23K 1/012; B23K 3/047; B23K 3/08; B23K 101/40

(52) U.S. Cl. CPC H01L 24/75; B23K 1/0016; B23K 1/002; B23K 1/012; B23K 3/0475; B23K 3/087; H01L 24/81; B23K 2101/40; H01L 2224/75252; H01L 2224/81815

(57) ABSTRACT

A reflow flip chip bonding tool apparatus is provided. The bonding tool apparatus includes a heater configured to heat air and a bonding tool body disposed on an upper surface of the chip, wherein a movement path is formed between a lower surface of the bonding tool body and the upper surface of the chip, the air heated by the heater heats the chip through non-contact convection heat transfer while flowing through the movement path, and a solder disposed between the lower surface of the chip and an electrode pad of the substrate is melted.

### CROSS-REFERENCE TO RELATED APPLICATIONS

This application claims the benefit of the Korean Patent Application Nos. 10-2023-0154279 filed on Nov. 9, 2023, and 10-2024-0079455 filed on Jun. 19, 2024, which are hereby incorporated by reference as if fully set forth herein.

### BACKGROUND

### Field of the Invention

The present invention relates to a reflow flip chip bonding tool apparatus, and more particularly, to a reflow flip chip bonding tool apparatus which may heat a flip chip through convection heat transfer using heated air to solder-bond the flip chip onto a substrate, in manufacturing an optical module and an electronic module.

### Discussion of the Related Art

As traffic of artificial intelligence (Al) data centers increases, the demands for high-speed optical transmitting/receiving modules for transmitting massive high-speed data are increasing. An interconnection between a substrate and an electronic device (for example, an optical source device, an optical receiving device, etc.) has been implemented as wire bonding, in packaging of a high-speed optical transmitting/receiving module.

Wire bonding is a process of connecting an electrode pad of an electronic device to an electrode pad of a substrate with a metal wire, and because a length of the metal wire is several to tens times a diameter of the electrode pad, the wire bonding is vulnerable to signal distortion caused by a parasitic component.

On the other hand, a flip chip bonding is a process of directly connecting an electrode pad of an electronic device to an electrode pad of a substrate with a soldering material, and because a length of a bonding part between the electronic device and the substrate is less than or similar to a diameter of the electrode pad, a parasitic component may be reduced. Due to this, flip chip bonding is increasingly issued in packaging for high-speed radio frequency (RF) transmission.

For solder melting for flip chip bonding, there is a method where, after a chip is picked up by using a bonding tool having a vacuum function, a substrate to which the chip is to be bonded is locally heated up to a melting temperature level of a solder by using a laser, or the chip picked up by the bonding tool is heated up to the melting temperature level of the solder by using the thermal conduction of the bonding tool.

In a flip chip bonding method using local heating by a laser, because the solder melting and position deviation of a previously bonded peripheral chip occur due to the peripheral thermal dissipation of heat absorbed onto a locally heated substrate, precise process condition setting and process control are needed.

In a flip chip bonding method using the thermal conduction of a bonding tool, as illustrated in FIG. 1, a surface contact for thermal conduction between a surface of a chip 10 and a surface of a bonding tool 30 is needed. In a case where the flatness of the surface of the bonding tool 30 is low, or pollutants such as particles are adsorbed onto the surface of the bonding tool 30 in the middle of a process, the chip 10 is non-uniformly heated because a non-uniform surface contact occurs between the surface of the chip 10 and the surface of the bonding tool 30, and due to this, there is a problem where some solders 15 do not reach up to a melting temperature level. For reference, FIG. 1 is a cross-sectional view of a reflow flip chip bonding tool apparatus of the related art. In FIG. 1, a reference numeral 40 refers to a heater which generates heat transferred to the chip 10 through the bonding tool 30, and a reference numeral 60 refers to a vacuum valve. The vacuum valve 60 discharges heated air, discharged through a tube 50 connected to an air outlet path 31 formed at a center of the bonding tool 30, to the outside having a vacuum state.

### SUMMARY

An aspect of the present invention is directed to providing a reflow flip chip bonding tool apparatus and an operating method thereof, which may heat a chip through non-contact convection heat transfer using heated air without a surface contact between a bonding tool and the chip and may bond the chip onto a substrate.

To achieve these and other advantages and in accordance with the purpose of the invention, as embodied and broadly described herein, there is provided a reflow flip chip bonding tool apparatus including: a heater configured to heat air; and a bonding tool body disposed on an upper surface of the chip, wherein a movement path is formed between a lower surface of the bonding tool body and the upper surface of the chip, the air heated by the heater heats the chip through non-contact convection heat transfer while flowing through the movement path, and a solder disposed between the lower surface of the chip and an electrode pad of the substrate is melted.

In an embodiment, a concave-convex pattern may be formed in the lower surface of the bonding tool body, and a groove formed by the concave-convex pattern may cause a vortex flow of the heated air.

In an embodiment, an air inlet path which vertically passes through the bonding tool body and is connected to the movement path may be formed at each of both end portions of the bonding tool body.

In an embodiment, an air outlet path, which vertically passes through the bonding tool body and discharges the heated air passing through the movement path to the outside, may be formed at a center of the bonding tool body.

In an embodiment, the reflow flip chip bonding tool apparatus may further include a vacuum valve configured to discharge the heated air, discharged through the air outlet path, to the outside.

In an embodiment, the reflow flip chip bonding tool apparatus may further include an air valve configured to allow the air to flow into the heater, based on an opening operation.

In an embodiment, the heater may include: a body including an internal path through which the air flows; and a heating cable configured to surround the body, convert electrical energy into thermal energy, and heat the air by using the thermal energy.

In an embodiment, the internal path may be formed in a zigzag form.

In another aspect of the present invention, there is provided an operating method of a reflow flip chip bonding tool apparatus, the operating method including: a step of loading a bonding tool body onto an upper surface of a chip disposed on a chip carrier by using a loading device in a state where an air valve connected to an air inlet path passing through both end portions of the bonding tool body and a vacuum valve connected to an air outlet path passing through a center of the bonding tool body are closed; a step of adsorbing and picking up the chip through vacuum adsorption of the vacuum valve by using the bonding tool body as the vacuum valve is changed from a closed state to an open state, based on control by a controller; a step of loading the picked-up chip onto a substrate by using the bonding tool body in a state where the picked-up chip is aligned at a position of an electrode pad formed in an upper surface of the substrate and a position of a solder formed in a lower surface of the chip; and a step of changing the air valve from a closed state to an open state, heating air flowing in through the opened air valve by using a heater disposed between the air valve and the air inlet path, heating the chip with the heated air through non-contact convection heat transfer while flowing through a movement path formed between a lower surface of the bonding tool body and the upper surface of the chip, and melting the solder, based on control by the controller.

In an embodiment, a vortex flow of the heated air may be caused by a groove of a concave-convex pattern formed in the lower surface of the bonding tool body.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a cross-sectional view of a reflow flip chip bonding tool apparatus of the related art.

FIG. 2 is a cross-sectional view of a reflow flip chip bonding tool apparatus according to an embodiment of the present invention.

FIG. 3 to FIG. 6 are cross-sectional views for describing an operating method of the reflow flip chip bonding tool apparatus illustrated in FIG. 2.

### DETAILED DESCRIPTION OF THE INVENTION

In the following description, the technical terms are used only for explain a specific exemplary embodiment while not limiting the present invention. The terms of a singular form may include plural forms unless referred to the contrary. The meaning of ‘comprise’, ‘include’, or ‘have’ specifies a property, a region, a fixed number, a step, a process, an element and/or a component but does not exclude other properties, regions, fixed numbers, steps, processes, elements and/or components.

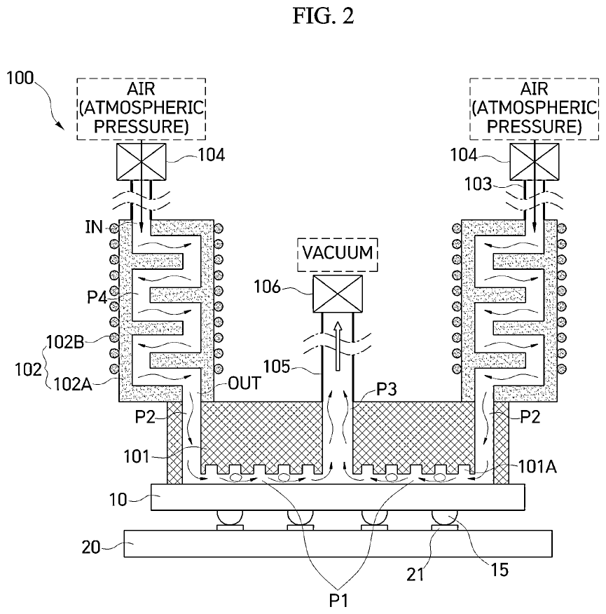

FIG. 2 is a cross-sectional view of a reflow flip chip bonding tool apparatus 100 according to an embodiment of the present invention.

Referring to FIG. 2, the reflow flip chip bonding tool apparatus 100 (hereinafter referred to as a bonding tool apparatus) according to an embodiment of the present invention may heat a chip 10 through non-contact convection heat transfer based on heated air to melt a solder 15 disposed between an electrode pad (not shown) of the chip 10 and an electrode pad 21 of a substrate 20 and may electrically and mechanically bond the chip 10 to the substrate 20 through a process of cooling the melted solder 15.

To this end, the bonding tool apparatus 100 may include a bonding tool body 101, a heater 102, an inlet tube 103, an air valve 104, an outlet tube 105, and a vacuum valve 106.

The bonding tool body 101 may be disposed on an upper surface of the chip 10 and may be apart therefrom by a certain interval. Therefore, a lower surface of the bonding tool body 101 may not directly contact the upper surface of the chip 10. However, an edge surface of the lower surface of the bonding tool body 101 may contact the upper surface of the chip 10.

A certain interval formed between the lower surface of the bonding tool body 101 and the upper surface of the chip 10 may function as a movement path P1 of air heated by the heater 102. The chip 10 may be heated through non-contact convection heat transfer based on heated air flowing through the movement path P1, and the solder 15 disposed between the electrode pad (not shown) of the chip 10 and the electrode pad 21 of a substrate 20 may be melted. At this time, a concave-convex pattern 101A may be formed in the lower surface of the bonding tool body 101.

A groove formed by the concave-convex pattern 101A may cause a vortex flow of heated air flowing through the movement path P1. Such a vortex flow may increase a convection heat transfer coefficient of the heated air to easily heat the chip 10 up to a melting temperature level of the solder 15.

The bonding tool body 101 may be manufactured with an insulating material such as graphite or ceramic, so as to minimize the heat dissipation of the heated air.

An air inlet path P2 vertically passing through the bonding tool body 101 may be formed at each of both end portions of the bonding tool body 101, and an air outlet path P3 vertically passing through the bonding tool body 101 may be formed at a center of the bonding tool body 101.

The air inlet path P2 and the air outlet path P3 may be connected to each other by the movement path P1. Therefore, air heated by the heater 101 may be flow into the air inlet path P2, and the heated air flowing into the air inlet path P2 may pass through the movement path P1 and may be discharged to the outside through the air outlet path P3. At this time, in order to easily discharge the heated air to the outside, the air outlet path P3 may be connected to the vacuum valve 106 by the outlet tube 105, and based on an opening operation of the vacuum valve 106, the heated air may be easily discharged to the outside having a vacuum state.

The heater 102 may be connected to the air valve 104 through the inlet tube 103 and may heat air which has an atmospheric state and flows in through the inlet tube 103, based on an opening operation of the air valve 104.

To this end, the heater 102 may include a body 102A and a heating cable 102B which surrounds the body 102A. The body 102A may include an inlet port IN connected to the inlet tube 103, an outlet port OUT connected to the air inlet path P2 of the bonding tool body 101, and an internal path P4 connecting the inlet portion IN to the outlet port OUT. The internal path P4 may be formed in a zigzag form. Therefore, the air which has an atmospheric state and flows in through the inlet tube 103 may pass through the internal path P4 in a zigzag form. The heating cable 102B may convert electrical energy into thermal energy. Such thermal energy may heat air passing through an inner portion of the body 102A. In this case, because the internal path P4 of the body 102A is formed in a zigzag form, air may absorb sufficient thermal energy while passing through the internal path P4 of the body 102A in a zigzag form. That is, the reason that the internal path P4 of the body 102A is formed in a zigzag form is because heat transfer efficiency is considered.

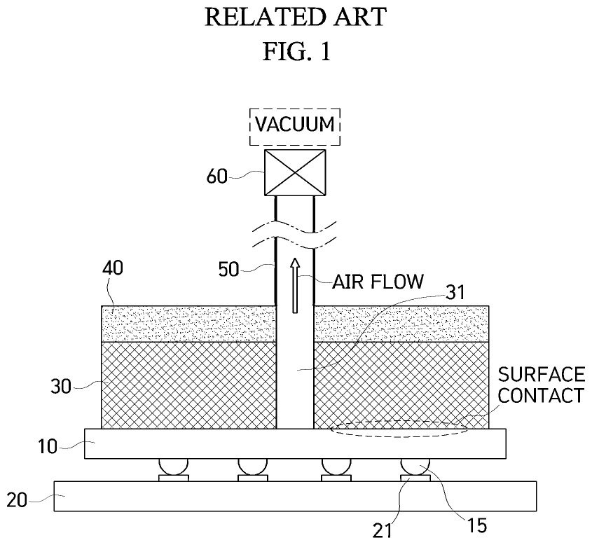

Furthermore, although not shown in FIG. 1, the bonding tool apparatus 100 may further include a power supply which supplies electrical energy to the heating cable 102B and a controller which controls an opening/closing operation of each of the air valve 104 and the vacuum valve 106 or a computing device which includes the controller. Here, the controller may include at least one central processing unit (CPU) and at least one memory. The memory may store instructions for controlling an overall operation of the bonding tool apparatus 100, and the instructions may be executed by the CPU.

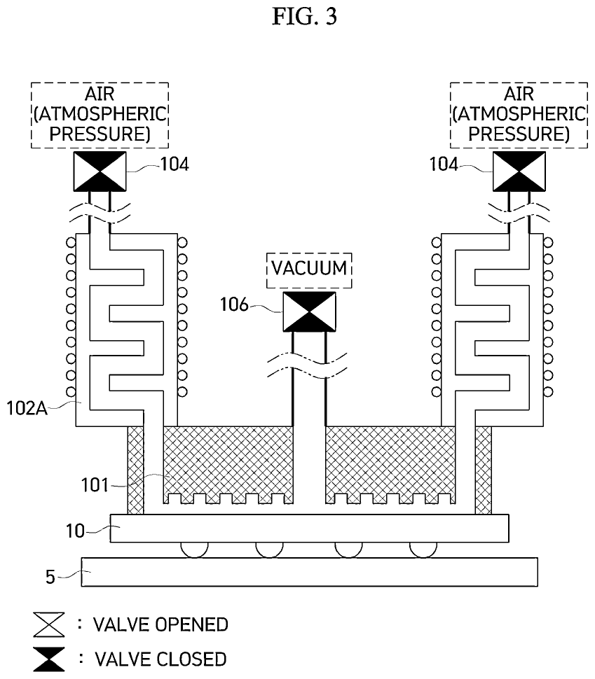

FIGS. 3 to 6 are cross-sectional views for describing an operating method of the reflow flip chip bonding tool apparatus illustrated in FIG. 2.

First, referring to FIG. 3, a controller (not shown) may close the air valve 104 and the vacuum valve 106, and a loading device (not shown) may load the edge surface of the lower surface of the bonding tool body 101 onto the upper surface of the chip 10 disposed on a chip carrier 5. The loading device for moving the bonding tool body 101 may be variously designed as a type such as a robot arm. The loading device may not be an essential feature of the present invention, and thus, a detailed description thereof is omitted.

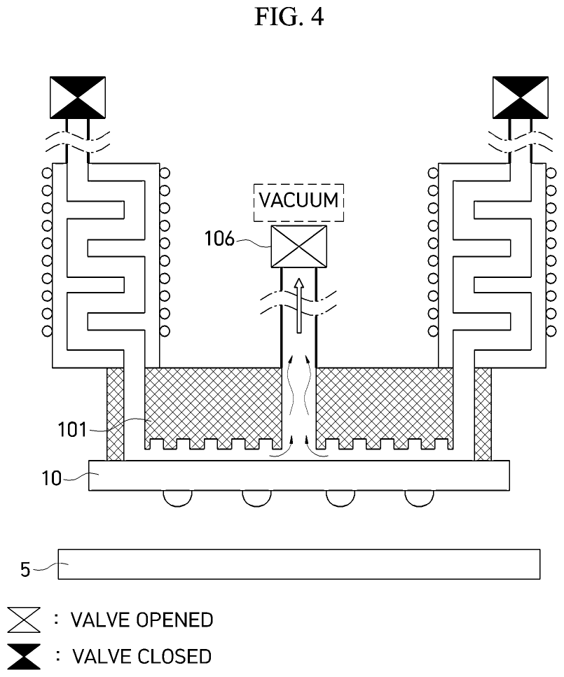

Subsequently, referring to FIG. 4, the controller (not shown) may open the vacuum valve 106, and thus, the bonding tool body 101 may adsorb and pick up the chip 10 disposed on the chip carrier 5, based on the vacuum adsorption of the vacuum valve 106.

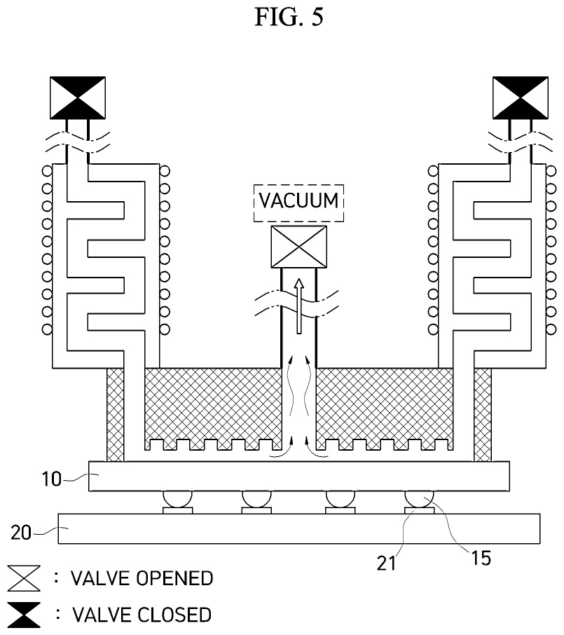

Subsequently, referring to FIG. 5, the bonding tool body 101 may align the picked-up chip 10 at a position of the electrode pad 21 formed on the upper surface of the substrate 20 and a position of the solder 15 formed on the lower surface of the chip 10, and then, may load the chip 10 onto the substrate 20.

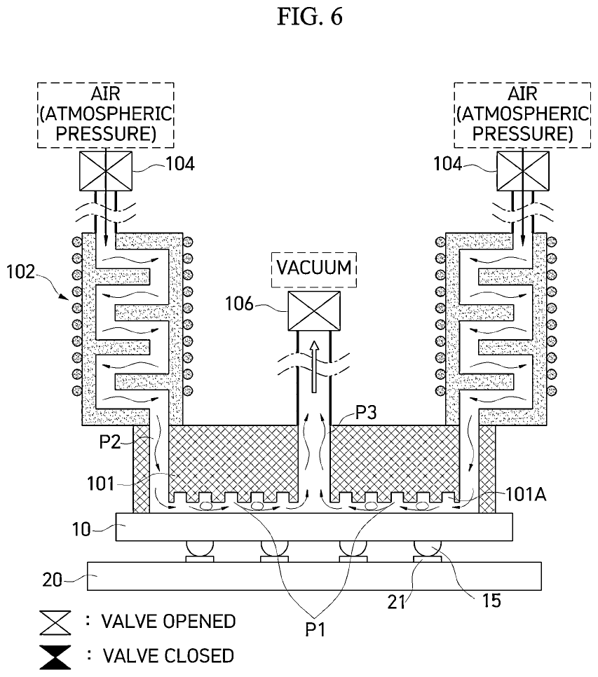

Subsequently, referring to FIG. 6, the controller may open the air valve 104, and air may flow into the heater 102 through the opened air valve 104. The heater 102 may heat the air flowing therein, based on a predetermined temperature profile, and the heated air may flow into the movement path P1 through the air inlet path P2 of the bonding tool body 101. The heated air flowing through the movement path P1 may heat the chip 10 through convection heat transfer, and solder bonding between the solder 15 and the electrode pad 21 may be performed by the heated chip 10. At this time, a vortex flow of the heated air may be caused by the concave-convex pattern 101A formed in the lower surface of the bonding tool body 101, and the vortex flow of the heated air may increase convection heat transfer efficiency. Also, the heated air passing through the movement path P1 may be discharged to the outside having an atmospheric state through the opened vacuum valve 106 via the air outlet path P3 passing through the center of the bonding tool body 101.

According to the embodiments of the present invention, as a chip is heated through non-contact heat transfer by using heated air sucked into a bonding tool, a direct surface contact between the chip and the bonding tool may be prevented, and the occurrence of pollution in a chip surface caused by the surface contact may be prevented. Also, because the direct surface contact between the chip and the bonding tool is prevented, a load applied to the chip may be minimized, thereby preventing the damage of the chip.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A reflow flip chip bonding tool apparatus comprising:
a heater configured to heat air; and
a bonding tool body disposed on an upper surface of the chip,
wherein a movement path is formed between a lower surface of the bonding tool body and the upper surface of the chip, the air heated by the heater heats the chip through non-contact convection heat transfer while flowing through the movement path, and a solder disposed between the lower surface of the chip and an electrode pad of the substrate is melted.

2. The reflow flip chip bonding tool apparatus of claim 1, wherein a concave-convex pattern is formed in the lower surface of the bonding tool body, and
a groove formed by the concave-convex pattern causes a vortex flow of the heated air.

3. The reflow flip chip bonding tool apparatus of claim 1, wherein an air inlet path which vertically passes through the bonding tool body and is connected to the movement path is formed at each of both end portions of the bonding tool body.

4. The reflow flip chip bonding tool apparatus of claim 1, wherein an air outlet path, which vertically passes through the bonding tool body and discharges the heated air passing through the movement path to the outside, is formed at a center of the bonding tool body.

5. The reflow flip chip bonding tool apparatus of claim 4, further comprising a vacuum valve configured to discharge the heated air, discharged through the air outlet path, to the outside.

6. The reflow flip chip bonding tool apparatus of claim 1, further comprising an air valve configured to allow the air to flow into the heater, based on an opening operation.

7. The reflow flip chip bonding tool apparatus of claim 1, wherein the heater comprises:
a body including an internal path through which the air flows; and
a heating cable configured to surround the body, convert electrical energy into thermal energy, and heat the air by using the thermal energy.

8. The reflow flip chip bonding tool apparatus of claim 7, wherein the internal path is formed in a zigzag form.

9. An operating method of a reflow flip chip bonding tool apparatus, the operating method comprising:
a step of loading a bonding tool body onto an upper surface of a chip disposed on a chip carrier by using a loading device in a state where an air valve connected to an air inlet path passing through both end portions of the bonding tool body and a vacuum valve connected to an air outlet path passing through a center of the bonding tool body are closed;
a step of adsorbing and picking up the chip through vacuum adsorption of the vacuum valve by using the bonding tool body as the vacuum valve is changed from a closed state to an open state, based on control by a controller;
a step of loading the picked-up chip onto a substrate by using the bonding tool body in a state where the picked-up chip is aligned at a position of an electrode pad formed in an upper surface of the substrate and a position of a solder formed in a lower surface of the chip; and
a step of changing the air valve from a closed state to an open state, heating air flowing in through the opened air valve by using a heater disposed between the air valve and the air inlet path, heating the chip with the heated air through non-contact convection heat transfer while flowing through a movement path formed between a lower surface of the bonding tool body and the upper surface of the chip, and melting the solder, based on control by the controller.

10. The operating method of claim 9, wherein a vortex flow of the heated air is caused by a groove of a concave-convex pattern formed in the lower surface of the bonding tool body.
